(19) United States
(12) Patent Application Publication
(10) Pub. No.: US 2025/0135690 A1
(43) Pub. Date: May 1, 2025

(54) IMPRINT APPARATUS, IMPRINT METHOD, AND MANUFACTURING METHOD OF ARTICLE

(71) Applicant: CANON KABUSHIKI KAISHA, Tokyo (JP)

(72) Inventor: NORIKAZU BABA, Tochigi (JP)

(21) Appl. No.: 18/911,580

(22) Filed: Oct. 10, 2024

(30) Foreign Application Priority Data
Oct. 31, 2023 (JP) 2023-186129

(51) Int. Cl. B29C 43/14; B29C 35/08; B29C 43/02; B29C 43/58; B29K 105/00; B29L 31/34; G03F 7/00

(52) U.S. Cl. CPC B29C 43/14; B29C 35/0805; B29C 43/021; B29C 43/58; G03F 7/0002; B29C 2043/023; B29C 2043/141; B29K 2105/0094; B29L 2031/3406

(57) ABSTRACT

To reduce an occurrence of a defect and a shear force occurring between a mold and a substrate, an imprint apparatus that brings a curable composition on a substrate and a mold into contact with each other to be cured, and molds the curable composition into a pattern shape of the mold includes an irradiation unit configured to irradiate the curable composition on the substrate with a first energy to increase a viscosity of the curable composition and a second energy to cure the curable composition, and a control unit configured to control the irradiation unit such that the curable composition on a specific region that is a part of a molding region of the substrate is irradiated with the first energy before the mold and the curable composition are brought into contact with each other, and the curable composition over an entire molding region of the substrate is irradiated with the second energy after the mold and the curable composition are brought into contact with each other.

### BACKGROUND OF THE INVENTION

### Field of the Invention

The present invention relates to an imprint apparatus, an imprint method, and a manufacturing method of an article.

### Description of the Related Art

In a nano-imprint technology for manufacturing an article such as a semiconductor device, a mold is brought into contact with an imprint material disposed on a substrate, and the imprint material is cured by irradiating the imprint material with curing energy such as ultraviolet light. As a result, a pattern formed on the mold is transferred to the imprint material, and a pattern of the imprint material is formed on the substrate.

In Japanese Unexamined Patent Application, First Publication No. 2019-106536, a nano-imprint technology is described in which a mold is brought into contact with a moldable material on a substrate, and then a specific region within a shot region formed on the substrate is irradiated with light to increase the viscosity of the imprint material. This makes it possible to prevent the imprint material from seeping out of the shot region.

In addition, in the nano-imprint technology, a pattern may be formed using a substrate onto which an imprint material has been uniformly applied in advance. In Japanese Unexamined Patent Application, First Publication No. 2013-171950, first, an entire surface of a resin on the substrate is semi-cured in this type of imprint.

Then, a hardness of a first portion, which is a part of the resin, is furthermore made harder than a hardness of a second portion, which is a part other than the first portion, and the template and the resin on the substrate are brought into contact with each other, thereby maintaining an accurate interval between the template and the substrate.

However, in Japanese Unexamined Patent Application, First Publication No. 2019-106536, a part of the imprint material on the substrate may adhere to the mold, causing a defect (herein referred to as a carryover defect) when a next shot region is imprinted.

To reduce such a defect, as in Japanese Unexamined Patent Application, First Publication No. 2013-171950, an entire surface of the shot region is irradiated with curing energy, and the viscosity of the imprint material is increased, thereby making it possible to suppress adhesion of the imprint material to the mold.

However, in this case, the viscosity of the imprint material increases, which can increase a shear force occurring between the mold and the substrate. When the shear force increases, it can inhibit a drive of the mold in a direction parallel to a surface of the substrate of the mold when relative alignment between the mold and the substrate is performed, so that it is difficult to suppress the carryover defect and to suppress the shear force at the same time.

### SUMMARY OF THE INVENTION

An imprint apparatus according to one aspect of the present invention is an imprint apparatus that brings a curable composition on a substrate and a mold into contact with each other to be cured, and molds the curable composition into a pattern shape of the mold, and includes an irradiation unit configured to irradiate the curable composition on the substrate with a first energy to increase a viscosity of the curable composition and a second energy to cure the curable composition, and a control unit configured to control the irradiation unit such that the curable composition on a specific region that is a part of a molding region of the substrate is irradiated with the first energy before the mold and the curable composition are brought into contact with each other, and the curable composition over an entire molding region of the substrate is irradiated with the second energy after the mold and the curable composition are brought into contact with each other.

Further features of the present invention will become apparent from the following description of embodiments with reference to the attached drawings.

### BRIEF DESCRIPTION OF THE DRAWINGS

FIG. 1 is a schematic diagram which shows a configuration of an imprint apparatus according to a first embodiment.

FIGS. 2A to 2C are diagrams which describe an occurrence of a carryover defect.

FIG. 3 is a diagram which describes irradiation of a specific area with a first irradiation light by a first light irradiation unit.

FIG. 4 is a flowchart which describes processing by the imprint apparatus according to the first embodiment.

FIG. 5 is a flowchart which describes processing by an imprint apparatus according to a second embodiment.

FIGS. 6A and 6B are diagrams which describe a specific area according to a third embodiment.

FIGS. 7A and 7B are diagrams which describe irradiation by a first light irradiation unit according to the third embodiment.

FIGS. 8A to 8F are diagrams for describing a manufacturing method of an article.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### First Embodiment

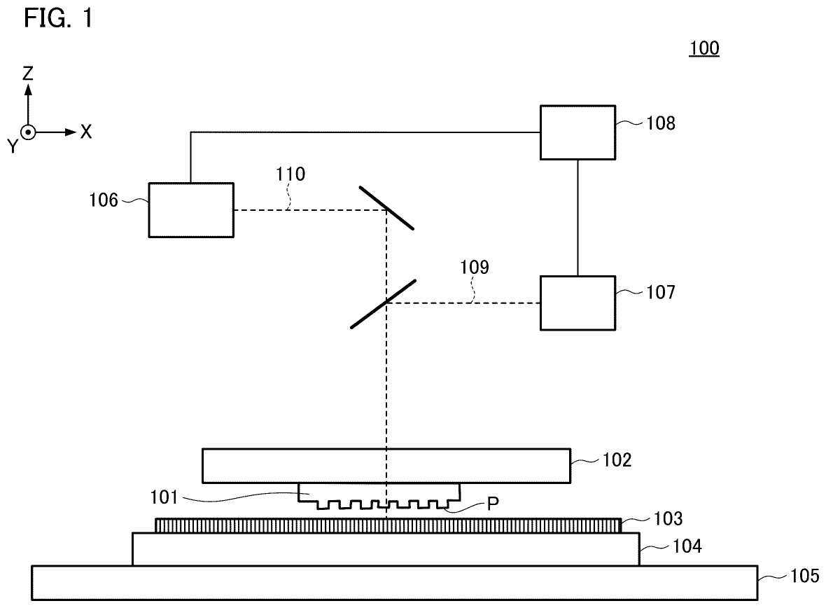

FIG. 1 is a schematic diagram which shows a configuration of an imprint apparatus 100 according to a first embodiment. The imprint apparatus 100 is used for manufacturing a device such as a semiconductor device.

The imprint apparatus 100 is an apparatus that brings an imprint material applied on a substrate into contact with a mold (also referred to as a template) and applies curing energy to the imprint material, thereby forming a pattern of a cured material to which a concave and convex pattern of the mold is transferred.

For example, the imprint apparatus 100 applies an imprint material onto a substrate, and cures the imprint material while a mold on which a concave and convex pattern is formed is brought into contact with the imprint material on the substrate.

Then, an interval between the mold and the substrate is widened, and the mold is peeled off (released) from the cured imprint material, so that a pattern of the mold can be formed in the imprint material on the substrate. Such a series of processing is called imprint processing, and is performed for each of a plurality of shot regions on the substrate.

In other words, when imprint processing is performed on each of the plurality of shot regions on one substrate, the imprint processing is repeatedly performed for the number of shot regions on one substrate.

Note that a shot region is a partitioned region that is a unit of a region on the substrate where imprint processing is to be performed. In the present embodiment, the shot region is a region of a size equivalent to a pattern portion P of the mold 101, which will be described below, and is a region (molding region) where a pattern of an imprint material corresponding to the pattern portion P of the mold 101 is formed in one imprint processing.

Here, an imprint apparatus 100 that employs a photocuring method will be described as an example. In the following drawings, a Z axis is parallel to an optical axis (a vertical direction) of an illumination system that irradiates the imprint material on the substrate with an irradiation light, and X and Y axes are orthogonal to each other in a plane perpendicular to the Z axis.

The imprint apparatus 100 includes an imprint head 102 that holds and moves up and down the mold 101 on which the pattern portion P is formed, and a substrate stage 105 that holds and moves a substrate 104 and aligns it with the mold 101.

Furthermore, the imprint apparatus 100 includes a first light irradiation unit 107 that irradiates a specific region on the substrate with light, a second light irradiation unit 106 that irradiates an entire surface of the shot region on the substrate with light, and a control unit 108 that controls these units.

The mold 101 has, for example, a rectangular outer peripheral shape, and a pattern portion P (also called a mesa) that protrudes from the periphery is provided near a center on the surface facing the substrate 104. An uneven pattern of a three-dimensional shape to be transferred, such as a circuit pattern, is formed in the pattern portion P. A material of the mold 101 is, for example, a material that can transmit ultraviolet light, and quartz is used as an example in the present embodiment.

The imprint head 102 is a mold holding unit that holds the mold 101. The imprint head 102 may have a driving mechanism that moves the mold 101 while holding it. The imprint head 102 can hold the mold 101 by attracting an outer peripheral region of a surface irradiated with curing energy in the mold 101 by a vacuum suction force or an electrostatic force.

The imprint head 102 moves the mold 101 in each axial direction to selectively press or separate the mold 101 and the imprint material 103 on the substrate 104. In addition, to accommodate high-precision positioning of the mold 101, the imprint head 102 may be configured with a plurality of drive systems, such as a coarse drive system and a fine drive system.

Furthermore, the imprint head 102 may have a constituent having a position adjustment function not only in a Z-axis direction, but also in an X-axis direction, a Y-axis direction, or a θ direction of each axis, and a tilt function for correcting an inclination of the mold 101. Pressing and separating operations in the imprint apparatus 100 may be realized by moving the mold 101 in the Z-axis direction, or may be realized by moving the substrate stage 105 in the Z-axis direction, or by moving both of them relatively.

The substrate 104 is, for example, a single crystal silicon substrate or a silicon on insulator (SOI) substrate, and the imprint material 103 is applied to a surface to be treated.

The substrate stage 105 is a substrate holding unit that holds the substrate 104 by, for example, a substrate chuck (not shown). The substrate stage 105 aligns the mold 101 with the shot region to be processed when the mold 101 and the imprint material 103 on the substrate 104 are brought into contact with each other.

The substrate stage 105 also has a stage drive mechanism (not shown) that allows it to move in each axial direction. The stage drive mechanism may be composed of a plurality of drive systems, such as a coarse drive system and a fine drive system, for each of the X-axis and Y-axis directions.

Furthermore, it may have a configuration of having a drive system for adjusting the position in the Z-axis direction, a function for adjusting the position of the substrate 104 in the θ direction, or a tilt function for correcting the inclination of the substrate 104.

The imprint material is a curable composition (sometimes called an uncured resin) that is cured when curing energy is applied. As the curing energy, electromagnetic waves, heat, and the like are used. As the electromagnetic waves, for example, light such as infrared rays, visible light, and ultraviolet rays whose wavelengths are selected from a range of 10 nm to 1 mm are used.

The curable composition is a composition that is cured by irradiation with light or by heating. Among them, the photocurable composition that is cured by light contains at least a polymerizable compound and a photopolymerization initiator, and may contain a non-polymerizable compound or a solvent as necessary.

The non-polymerizable compound is at least one selected from a group consisting of a sensitizer, a hydrogen donor, an internal mold release agent, a surfactant, an antioxidant, a polymer component, and the like. In the present embodiment, as an example, a photocurable composition that is cured by light is used as the imprint material 103.

The imprint material is applied in a form of a film on the substrate by a spin coater or a slit coater. Alternatively, the imprint material may be applied onto the substrate in a form of droplets, or in a form of islands or a film formed by connecting a plurality of droplets, using a liquid ejection head.

The viscosity of the imprint material (viscosity at 25° C.) is, for example, 1 mPa·s or more and 100 mPa·s or less. In the present embodiment, an example in which the imprint material 103 is applied onto the substrate in the form of a film in advance will be described.

The first light irradiation unit 107 is an irradiation mechanism that performs the irradiation with the first irradiation light 109 to increase the viscosity of the imprint material 103 on a specific region within the shot region of the substrate 104. Details of the specific region will be described below.

The first light irradiation unit 107 includes a light source (not shown) for photopolymerizing the imprint material 103, in other words, a light source (light source for photopolymerization reaction) that emits light for increasing the viscosity of the imprint material 103.

In the present embodiment, the light source for photopolymerization reaction uses, as an example, a light source with a wavelength different from that of a light source of the second light irradiation unit 106. The first irradiation light emitted from the light source for photopolymerization reaction may be light as long as it causes the imprint material 103 to polymerize, and the present invention is not limited to ultraviolet light.

The light source for photopolymerization reaction is selected from those that can obtain a light output required for polymerizing the imprint material 103 to a desired viscosity, and examples of such light source include a lamp, a laser diode, and an LED.

The first irradiation light emitted from the light source for photopolymerization reaction is guided to a spatial light modulation element that spatially modulates an amplitude, a phase, or polarization by an optical element or the like. As the spatial light modulation element, for example, a digital micromirror device (hereinafter, DMD) can be adopted.

The DMD disposes a plurality of mirror elements on the light reflecting surface, and it is possible to change a distribution of the amount of irradiation by individually adjusting a surface direction of each mirror element. By using a spatial light modulation element such as a DMD, it becomes possible to freely set a shape and an intensity of an irradiation region (an irradiation range) of an irradiation light.

The second light irradiation unit 106 is an irradiation mechanism that irradiates the imprint material 103 in an entire shot region to be processed with a second irradiation light 110 after the mold 101 and the imprint material 103 on the substrate 104 are brought into contact with each other.

Here, the second irradiation light 110 is, for example, ultraviolet light, and is energy with a wavelength that cures the imprint material. The second light irradiation unit 106 may include, for example, a light source (not shown) and an optical element that adjusts the ultraviolet light emitted from the light source to light suitable for imprinting. The second light irradiation unit 106 and the first light irradiation unit 107 constitute an irradiation unit.

The control unit 108 is a control unit that includes a processing unit such as a CPU or other processor, or an FPGA, and a storage unit such as a memory, and controls an entire imprint apparatus 100. Specifically, the control unit 108 controls the imprint head 102, the substrate stage 105, the second light irradiation unit 106, and the first light irradiation unit 107.

The control unit 108 may be installed inside the imprint apparatus 100, or may be installed at a location separate from the imprint apparatus 100 and controlled remotely.

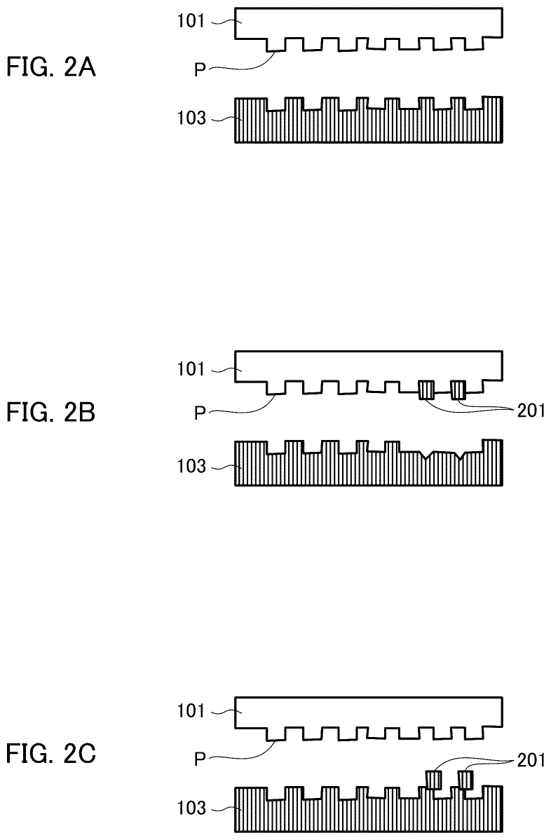

FIG. 2A to 2C are diagrams for describing an occurrence of a carryover defect. In imprint processing, a part of the imprint material 103 on the substrate 104 may adhere to the mold 101 and become a defect during imprint processing of a next shot region. Such a defect is referred to as a carryover defect in this specification.

FIG. 2A shows a state in which the mold 101 is normally released from the imprint material 103 on the substrate 104 and a pattern of the imprint material 103 is formed on the substrate. That is, FIG. 2A shows a state in which a defect does not occur and a pattern is normally formed.

FIG. 2B shows a state in which an adhesive material 201 of the imprint material 103 on the substrate 104 adhere to the mold 101 when the mold 101 is released from the imprint material.

FIG. 2C shows a state in which the mold 101 is released from the imprint material 103 on the substrate 104 in the imprint processing performed next to FIG. 2B. FIG. 2C shows that the adhesive material 201 that has adhered to the mold 101 in the previous imprint processing (imprint processing shown in FIG. 2B) adheres to the imprint material 103 on the substrate 104, and becomes a defect (a carryover defect).

In the present embodiment, to reduce the occurrence of such a carryover defect, a specific region in the shot region is irradiated with light by a first light irradiation unit 107 before the mold 101 and the imprint material 103 on the substrate 104 are brought into contact.

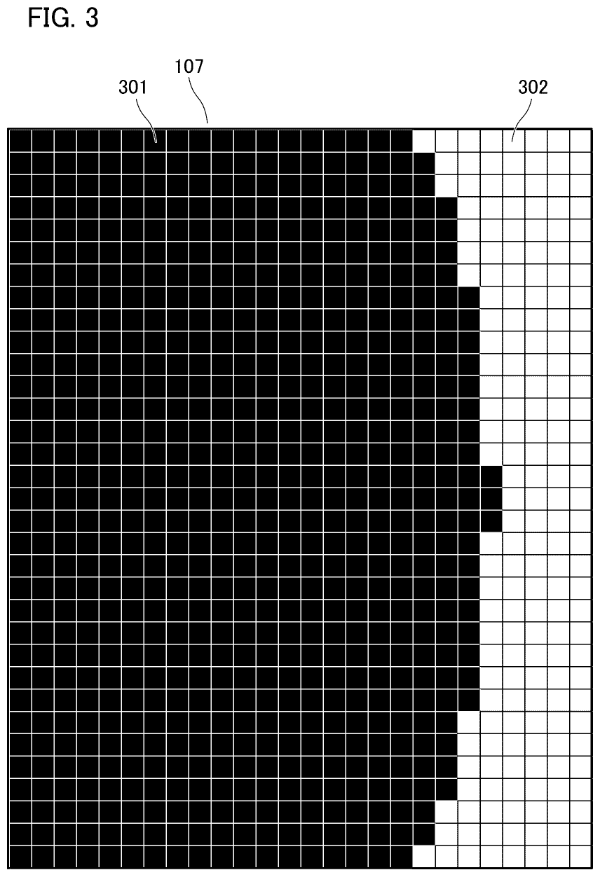

FIG. 3 is a diagram which describes the irradiation of a specific region with a first irradiation light by the first light irradiation unit 107. The first light irradiation unit 107 has a plurality of irradiation cells (301 and 302) for irradiating the shot region with the first irradiation light 109.

By switching between ON and OFF of each cell, it is possible to irradiate any range in the shot region. That is, the first light irradiation unit 107 can freely change a shape of the region (range) irradiated with the first irradiation light 109.

In FIG. 3, cells that are turned off are shown as off cells 301 in black, and cells that are turned on are shown as on cells 302 in white. The viscosity of the imprint material 103 in the region corresponding to the on cells 302, in other words, the imprint material 103 in the region irradiated through the on cells 302, increases.

As a result, when the mold 101 and the imprint material 103 on the substrate 104 are brought into contact with each other, it is possible to reduce adhesion of the adhesive material 201 of the imprint material 103 to the mold 101.

A purpose of the irradiation by the first light irradiation unit 107 is to reduce the adhesion of the adhesive material 201 of the imprint material 103 to the mold 101, so that it is desirable to perform the irradiation before the mold 101 and the imprint material 103 on the substrate 104 are brought into contact with each other.

In addition, it is desirable that the irradiation by the first light irradiation unit 107 be limited to a specific region. The first light irradiation unit 107 irradiates an entire shot region, which is a target of the imprint processing, before the mold 101 and the imprint material 103 are brought into contact with each other.

Then, a shear force between the mold 101 and the substrate 104 can be increased by the imprint material 103 whose viscosity has increased due to the irradiation by the first irradiation light 109. When the shear force becomes increased, it may inhibit a drive of the mold 101 in a direction parallel to a surface of the substrate 104 (an XY direction in FIG. 1) when relative alignment between the mold 101 and the substrate 104 is performed, and may hinder imprint processing.

Note that the specific region is a region in the shot region where a carryover defect is likely to occur. For example, a region in the shot region where a carryover defect is likely to occur may be identified by an experiment or the like, and the identified region may be set in advance as the specific region.

In addition, for example, an edge (an outer edge) of the substrate 104 and its periphery, and a notch or orientation flat formed in the substrate 104 and its periphery may be set as the specific region.

Furthermore, when the shot region that is a target of imprint processing is a shot region that does not include the edge of the substrate 104, which is called a full field, a frame-shaped region (a region along a circumference of the shot region) that is the periphery of the shot region may be the specific region.

In this case, the specific region is classified into a plurality of types according to characteristics of the specific region, such as a region including an edge, a region including a notch, and a frame-shaped region. Then, an amount of the irradiation with the first irradiation light 109 with which the specific region is irradiated may be determined according to the characteristics. That is, the first light irradiation unit 107 irradiates each specific region with the first irradiation light 109 with the amount of irradiation according to the characteristics of the specific region.

In addition, it is desirable that the amount of irradiation with the first irradiation light 109 by the first light irradiation unit 107 is determined so that the occurrence of carryover defects can be reduced and the shear force generated between the mold 101 and the substrate 104 is decreased.

By increasing the amount of irradiation, an effect of reducing the occurrence of carryover defects increases, but the possibility of shear force occurring between the mold 101 and the substrate 104 increases. For this reason, the amount of irradiation is determined by an experiment or the like so that an occurrence rate of carryover defects is equal to or less than a threshold value and the shear force is also equal to or less than a threshold value.

When the shear force occurring between the mold 101 and the substrate 104 increases, it is also necessary to increase a drive amount (an operation amount) of the substrate stage 105 in a direction parallel to the surface of the substrate 104 when relative alignment between the mold 101 and the substrate 104 is performed.

Therefore, the amount of irradiation of the first irradiation light 109 may be determined so that the drive amount of the substrate stage 105 when the relative alignment between the mold 101 and the substrate 104 is performed is equal to or less than a threshold value.

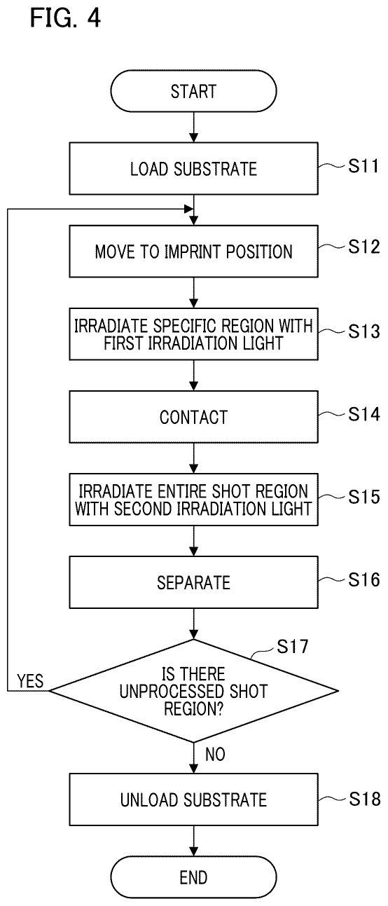

FIG. 4 is a flowchart which describes processing by the imprint apparatus 100 according to the first embodiment. A computer in the control unit 108 executes a computer program stored in a memory to perform an operation of each step in the flowchart in FIG. 4. Description of a loading of the mold 101 into the imprint head 102 and an unloading of the mold 101 from the imprint head 102 is omitted.

In S11, the substrate 104 subjected to imprint processing is transported to the substrate stage 105. In the present embodiment, the substrate 104 is loaded to the imprint apparatus 100 with the imprint material 103 applied to it in advance.

In S12, the substrate stage 105 is moved so that the shot region on the substrate 104 to be subjected to imprint processing next is positioned at a position (an imprint position) facing the pattern portion P of the mold 101.

In S13, the first light irradiation unit 107 irradiates the specific region on the shot region which is a target of imprint processing this time with the first irradiation light 109 to increase the viscosity of the imprint material 103 in the specific region.

In S14, the imprint head 102 is lowered to bring the pattern portion P of the mold 101 into contact with the imprint material 103 on the shot region. At this time, the substrate stage 105 may be raised to bring the pattern portion P of the mold 101 into contact with the imprint material 103 on the shot region.

Also, both the imprint head 102 and the substrate stage 105 may be driven. Then, the relative alignment of the pattern portion P and the shot region is performed. The alignment is performed by, for example, driving the substrate stage 105.

In S15, the second light irradiation unit 106 is used to irradiate the imprint material 103 in the entire shot region with the second irradiation light 110, thereby curing the imprint material 103.

In S16, the imprint head 102 is raised and the mold 101 is separated from the substrate 104. In S17, it is determined whether there is an unprocessed shot region. When there is an unprocessed shot region (Yes), the processing returns to S12 and the substrate 104 is moved to a next imprint position.

When there is no unprocessed shot region (No), the processing proceeds to S18. In S18, the substrate 104 is unloaded from the substrate stage 105 and the processing ends. That is, in the present embodiment, the imprint apparatus 100 executes imprint processing in which the irradiation of the specific region with the first irradiation light 109 (S13) and the irradiation of to the entire shot region with the second irradiation light 110 (S15) are repeated for each shot region.

According to the present embodiment, it is possible to reduce the occurrence of carryover defects by increasing the viscosity of the imprint material 103 in the specific region before the mold 101 and the imprint material 103 on the substrate 104 are brought into contact with each other.

In addition, since the viscosity of only the imprint material 103 in the specific region is increased, it is also possible to prevent an increase in the shear force between the mold 101 and the substrate 104. In other words, it is possible to reduce the occurrence of defects and to reduce the shear force occurring between the mold and the substrate.

Note that the present embodiment is also applicable to an imprint apparatus in a manner in which the imprint material 103 is supplied for each shot region within the imprint apparatus. In addition, the first light irradiation unit 107 and the second light irradiation unit 106 may be an integrated unit.

### Second Embodiment

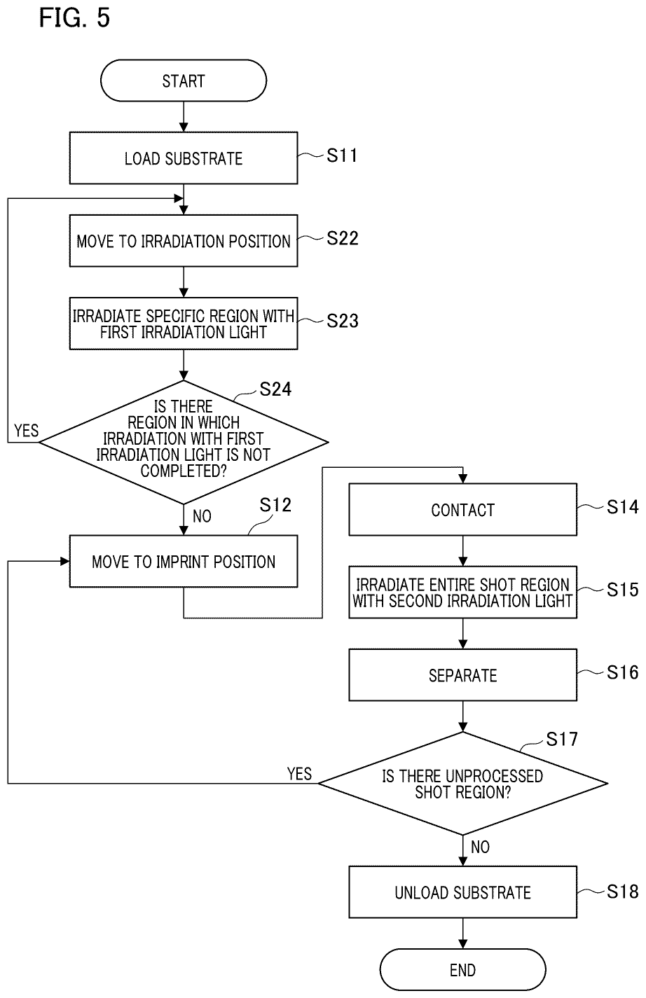

FIG. 5 is a flowchart for describing the processing by the imprint apparatus 100 according to a second embodiment. A computer in the control unit 108 executes a computer program stored in a memory to perform an operation of each step in the flowchart in FIG. 5. The same reference numbers are denoted for the same steps as those in the flowchart in FIG. 4 of the first embodiment, and the description will be omitted.

After the substrate is loaded (S11), in S22, the substrate stage 105 is moved so that the shot region to be irradiated with the first irradiation light 109 next becomes a position (an irradiation position) where the irradiation with the first irradiation light 109 can be performed by the first light irradiation unit 107.

In other words, the substrate stage 105 is moved to a position where a specific region in the shot region becomes within the irradiation region of the first irradiation light 109. The irradiation position may be the same as the imprint position.

In S23, the first light irradiation unit 107 irradiates the specific region on the shot region disposed at the irradiation position with the first irradiation light 109 to increase the viscosity of the imprint material 103 in the specific region.

In S24, it is determined whether there is a shot region in which the irradiation with the first irradiation light has not been completed. When there is an incomplete shot region (Yes), the processing returns to S22 and the substrate 104 is moved to a next irradiation position. When there is no incomplete shot region (No), the processing proceeds to S12.

In S12, the substrate stage 105 is moved so that the shot region on the substrate 104 to be subjected to a next imprint processing is positioned at a position (imprint position) facing the pattern portion P of the mold 101. Then, S14 to S18 are performed.

In this manner, first, before the mold 101 and the imprint material 103 are brought into contact with each other, the irradiation of the entire specific region on the substrate 104 with the first irradiation light 109 is executed (S22 to S24). Then, the mold 101 and the imprint material 103 on each shot region may be brought into contact with each other subsequently (S12 to S17) to form a pattern shape of the mold 101 on each shot region.

Here, first, all specific regions on the substrate 104 are irradiated with the first irradiation light 109 (S22 to S24). However, for example, the processes of S22 to S24 and S12 to S17 may be repeated for each of a predetermined number of shot regions.

Specifically, the irradiation of a predetermined number of specific regions with the first irradiation light 109 is executed, and then the imprint material 103 and the mold 101 on the shot regions where the irradiation with the first irradiation light 109 has been completed are sequentially brought into contact with each other. This processing is repeated until there are no more unprocessed shot regions.

### Third Embodiment

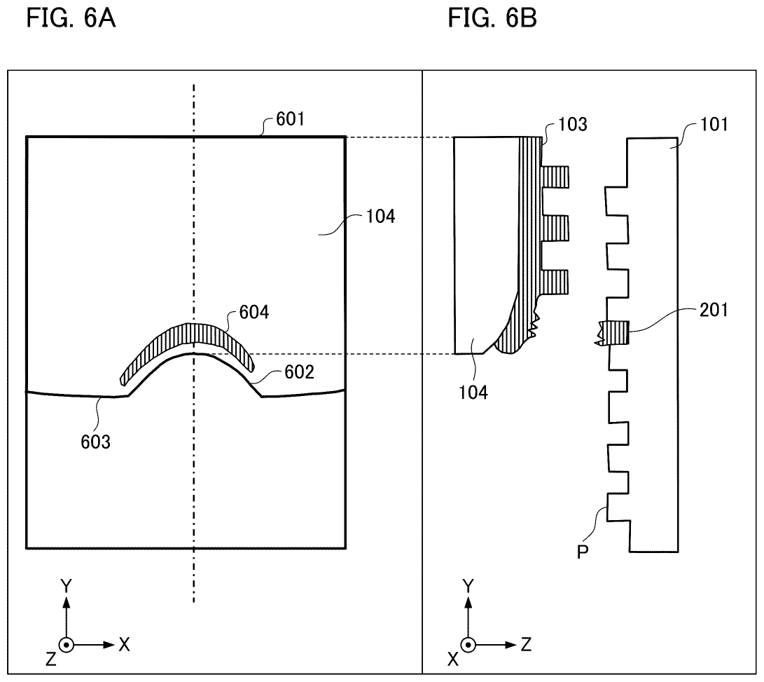

FIGS. 6A and 6B are diagrams for describing a specific region according to a third embodiment. FIG. 6A is a diagram which shows a shape of a notch 602 on the substrate 104. In FIG. 6A, a shot region 601 includes an edge 603 (outer edge) of the substrate 104.

The substrate 104 may have a cut (a cutout) called a notch. FIG. 6B shows a state in which the mold 101 is released from the imprint material 103 on the substrate 104 during imprint processing of a shot region including the notch 602.

The surface of the substrate 104 is not flat in a periphery 604 of the notch 602, and is inclined toward the edge 603, so that a distance (an interval) between the mold 101 and the substrate 104 is greater than usual. For this reason, the adhesive material 201 of the imprint material is likely to occur in the periphery 604 of the notch 602, as shown in FIG. 6B, and this is likely to cause a carryover defect.

In the present embodiment, to reduce the occurrence of such a carryover defect, a region including the notch 602 and its periphery 604 is set as a specific region.

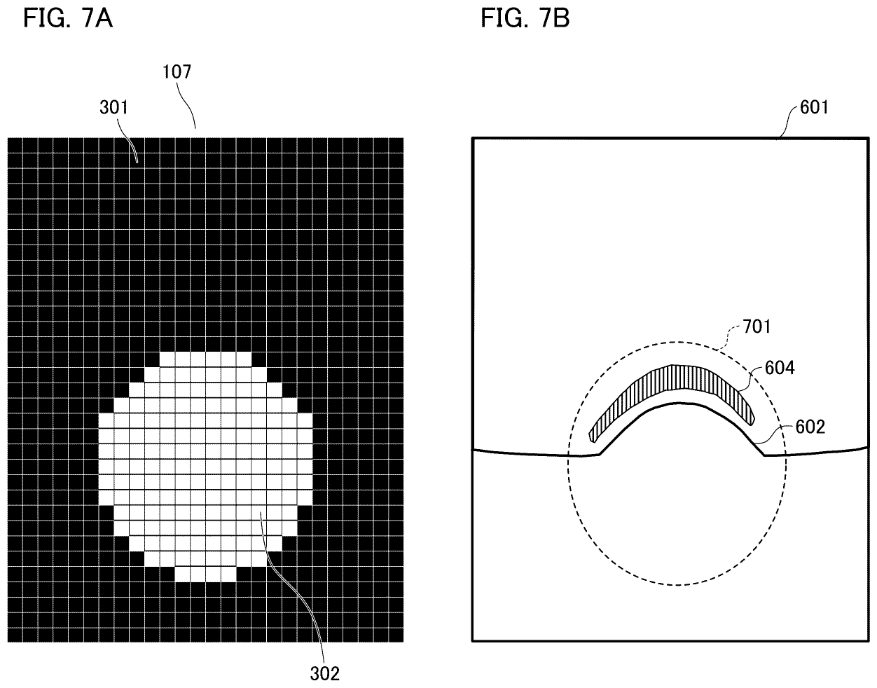

FIGS. 7A and 7B are diagrams which describe the irradiation by the first light irradiation unit 107 according to the third embodiment. FIG. 7A is a schematic diagram which shows settings of an irradiation cell of the first light irradiation unit 107.

As shown in FIG. 7A, the irradiation region of the first light irradiation unit 107 is controlled by switching the irradiation cell of the first light irradiation unit 107 between on and off so that the specific region including the notch 602 and its periphery 604 is irradiated with the first irradiation light 109. In FIG. 7A, the off cell 301 is shown in black and the on cell 302 is shown in white.

FIG. 7B is a schematic diagram which shows an example of an irradiation region 701 of the first irradiation light 109. Specifically, FIG. 7B shows the irradiation region 701 irradiated under control of the first light irradiation unit 107 as shown in FIG. 7A.

Here, a specific region including the notch 602 and its periphery 604 is contained (positioned) within the irradiation region 701. For this reason, the notch 602 and its periphery 604 are irradiated with the first irradiation light 109 before the mold 101 and the imprint material 103 on the substrate 104 are brought into contact with each other, and the viscosity of the imprint material 103 in the notch 602 and its periphery 604 increases.

As a result, when the mold 101 is released from the imprint material 103 on the substrate 104, the adhesion of the adhesive material 201 of the imprint material 103 to the mold 101 can be reduced.

Note that here, the first light irradiation unit 107 is controlled so that the irradiation region 701 is circular, but a shape of the irradiation region 701 is not limited to this as long as the specific region is included in the irradiation region 701.

For example, the shape may be semicircular or semicircular. However, it is desirable that the shape of the irradiation region 701 is easy to specify. When the shape of the irradiation region 701 is circular, it is desirable because the irradiation region can be specified with fewer parameters.

### Embodiment of Article Manufacturing Method

The pattern of the cured product formed using the imprint apparatus is used permanently as at least a part of various articles, or temporarily when various articles are manufactured. An article is an electric circuit element, an optical element, a MEMS, a recording element, a sensor, a mold, or the like.

The electric circuit element may be a volatile or non-volatile semiconductor memory such as a DRAM, an SRAM, a flash memory, or an MRAM, or a semiconductor element such as LSI, CCD, an image sensor, or an FPGA. An imprint mold or the like may be included as a mold.

The pattern of the cured product is used as it is as at least a part of constituent members of the article described above, or is used temporarily as a resist mask. After etching or ion implantation is performed in a processing step of the substrate, the resist mask is removed.

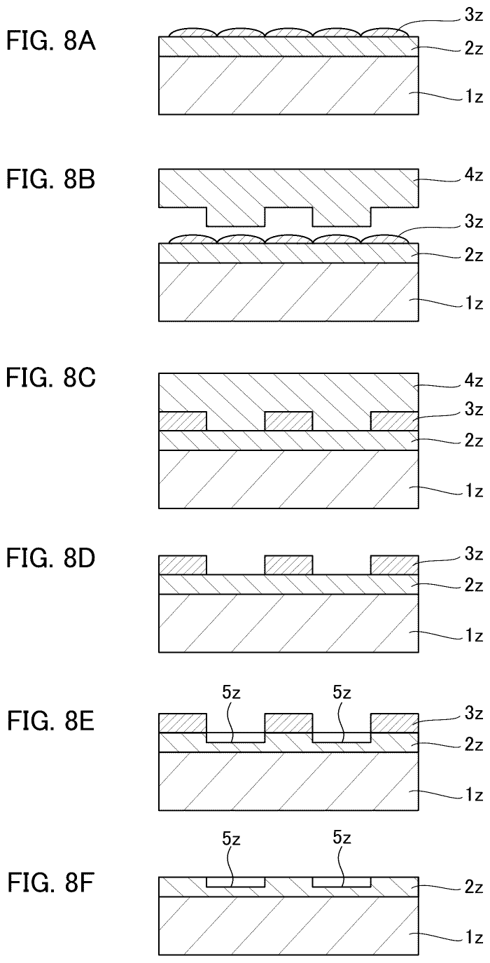

Next, a specific manufacturing method of the article will be described. FIGS. 8A to 8F are diagrams for describing the manufacturing method of an article. As shown in FIG. 8A, a substrate 1z such as a silicon wafer with a workpiece 2z such as an insulator formed on its surface is prepared, and then an imprint material 3z is applied to the surface of the workpiece 2z by an inkjet method or the like. Here, a state in which an imprint material 3z in a form of a plurality of droplets is applied onto the substrate is shown.

As shown in FIG. 8B, an imprint mold 4z is placed facing a side on which the concave and convex pattern is formed toward the imprint material 3z on the substrate. As shown in FIG. 8C, the substrate 1z to which the imprint material 3z has been applied and the mold 4z are brought into contact and pressure is applied.

The imprint material 3z fills a gap between the mold 4z and the workpiece 2z. When irradiation is performed with light through the mold 4z as curing energy in this state, the imprint material 3z is cured.

As shown in FIG. 8D, after the imprint material 3z is cured, when the mold 4z and the substrate 1z are separated, a pattern of the cured imprint material 3z is formed on the substrate 1z. The pattern of the cured material has a shape in which a concave portion of the mold corresponds to a convex portion of the cured material, and a convex portion of the mold corresponds to a concave portion of the cured material, that is, the concave and convex pattern of the mold 4z is transferred to the imprint material 3z.

As shown in FIG. 8E, when etching is performed using the pattern of the cured material as an etching-resistant mask, parts of a surface of the workpiece 2z where there is no cured material or where only a thin layer remains are removed to form grooves 5z. As shown in FIG. 8f, when the pattern of the cured material is removed, an article with grooves 5z formed on the surface of the workpiece 2z can be obtained.

Here, the pattern of the cured material is removed, but it may be used as, for example, an interlayer insulating film included in a semiconductor element or the like, that is, a constituent member of the article, without being removed after processing. Note that, although an example of using a mold for transferring a circuit pattern provided with a concave and convex pattern as the mold 4z has been described, a member having a flat surface without the concave and convex pattern (a flat template) may also be used.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the imprint apparatus and the like through a network or various storage media. Then, a computer (or a CPU, an MPU, or the like) of the imprint apparatus and the like may be configured to read and execute the program. In such a case, the program and the storage medium storing the program configure the present invention.

In addition, the present invention includes those realized using at least one processor or circuit configured to perform functions of the embodiments explained above. For example, a plurality of processors may be used for distribution processing to perform functions of the embodiments explained above.

This application claims the benefit of priority from Japanese Patent Application No. 2023-186129, filed on Oct. 31, 2023, which is hereby incorporated by reference herein in its entirety.

1. An imprint apparatus that brings a curable composition on a substrate and a mold into contact with each other to be cured, and molds the curable composition into a pattern shape of the mold, comprising:
an irradiation unit configured to irradiate the curable composition on the substrate with a first energy to increase a viscosity of the curable composition and a second energy to cure the curable composition; and
at least one processor or circuit configured to function as
a control unit configured to control the irradiation unit such that the curable composition on a specific region that is a part of a molding region of the substrate is irradiated with the first energy before the mold and the curable composition are brought into contact with each other, and the curable composition over an entire molding region of the substrate is irradiated with the second energy after the mold and the curable composition are brought into contact with each other.

2. The imprint apparatus according to claim 1,
wherein the irradiation unit includes a first irradiation mechanism that irradiates the specific region with the first energy and a second irradiation mechanism that irradiates the molding region with the second energy, and
the first irradiation mechanism is capable of changing a shape of a region to be irradiated with the first energy.

3. The imprint apparatus according to claim 1,
wherein the control unit executes imprint processing in which the irradiation of the specific region with the first energy and the irradiation of the molding region with the second energy are repeated for each molding region.

4. The imprint apparatus according to claim 1,
wherein the control unit executes the irradiation of all of the specific regions on the substrate with the first energy before the mold and the curable composition are brought into contact with each other, and then executes imprint processing to form the pattern shape on each molding region by sequentially bringing the mold and the curable composition on each molding region into contact with each other.

5. The imprint apparatus according to claim 1,
wherein the specific regions on the substrate are classified into a plurality of types according characteristics of the specific regions, and
the irradiation unit irradiates each of the specific regions with the first energy in an amount of irradiation that corresponds to characteristics of the specific regions.

6. The imprint apparatus according to claim 1,
wherein the irradiation unit irradiates the specific region with the first energy in an amount of irradiation such that a drive amount of a substrate holding unit is equal to or less than a threshold value when the mold and the substrate are aligned after the mold and the curable composition are brought into contact with each other.

7. The imprint apparatus according to claim 1,
wherein the specific region is a region including a notch formed in the substrate and its periphery.

8. The imprint apparatus according to claim 1,
wherein the curable composition is applied to the substrate in advance.

9. An imprint method in which a curable composition on a substrate and a mold are brought into contact with each other to be cured, and the curable composition is molded into a pattern shape of the mold, comprising:
irradiating the curable composition on a specific region that is a part of a molding region of the substrate with a first energy to increase a viscosity of the curable composition before the mold and the curable composition are brought into contact with each other; and irradiating the curable composition over an entire molding region of the substrate with a second energy to cure the curable composition after the mold and the curable composition are brought into contact with each other.

10. An article manufacturing method comprising:
a step of molding a curable composition on a substrate using the imprint apparatus according to claim 1; and
a step of processing the substrate through the step of molding,
wherein an article is manufactured from the substrate through the step of processing.
